(19) United States
(12) Patent Application Publication
(10) Pub. No.: US 2010/0242619 A1
(43) Pub. Date: Sep. 30, 2010

(54) SYSTEM AND METHOD FOR PREVENTING STRAIN CAUSED ERRORS IN FIBER OPTIC SENSORS

(75) Inventors: Michel Le Blanc, Houston, TX (US); Gerald Baker, Calabasas, CA (US)

Correspondence Address: FULWIDER PATTON LLP, HOWARD HUGHES CENTER, 6060 CENTER DRIVE, TENTH FLOOR, LOS ANGELES, CA, 90045, US

(73) Assignee: SABEUS, INC., Calabasas, CA (US)

(21) Appl. No.: 12/712,390

(22) Filed: Feb. 25, 2010

Related U.S. Application Data
(60) Provisional application No. 61/155,457, filed on Feb. 25, 2009.

(51) Int. Cl. G01L 1/24; H05K 13/00

(52) U.S. Cl. 73/800; 29/592.1; 29/593

(57) ABSTRACT

An encapsulated fiber Bragg grating sensor is provided wherein the EFL of sensor as well as the coefficient of friction between the sensor and the encapsulating tubing is controlled to minimize measurement errors caused by tensile and compressive strains. A method of manufacturing such a sensor is also provided.

### CROSS-REFERENCES TO RELATED APPLICATIONS

This application claims priority from U.S. Provisional Application No. 61/155,457, filed Feb. 25, 2009 incorporated by reference in its entirety.

### BACKGROUND OF THE INVENTION

Generally, the invention is directed to the constructions of fiber optic grating sensors, and more specifically, to systems and method for reducing or eliminating sensor errors caused by tensile and/or compressive strains due to frictional interaction between the optical fiber and the wall of an encapsulating tube.

Fiber optic sensors are used for many applications, including sensing pressure and temperature. In many instances, fiber Bragg gratings are used as the sensing elements. When used to measure temperature, elastic strain on the grating should be minimized to ensure accuracy of the sensor. Control of the elastic strain on the sensor is accomplished either by using short free lengths of fiber, or mounting the grating on a support structure such the strain state of the fiber Bragg grating is uniquely determined by the temperature. For example, the fiber Bragg grating may be mounted to a metallic support which is free to expand or contract with temperature, resulting in a predictable response of the fiber Bragg grating to temperature changes. Alternatively, the strain on the fiber Bragg grating can be measured and then subtracted from the grating reading.

Achieving full decoupling of strain, or a one-to-one relation between strain and temperature is difficult to achieve in long lengths of fiber optic cable. This problem also occurs where the fiber is encapsulated in a tubing for protection in harsh environments. Even when encapsulated, a loose fiber may still contact the walls of the tube and the friction present between the fiber and the tube wall can result in significant strains being imparted to the fiber and any fiber grating formed therein, causing potentially significant errors in measurement taken using fiber sensors.

Similarly, the inventors have found that complete elimination of friction can also be undesirable. For example, in a vertical well, the weight of a length of fiber causes tensile strains in the fiber that can result in the accumulation of large errors; it may also be impossible to determine what percentage of the weight of the fiber located below a particular section of the fiber is seen by the particular section of the fiber, thus that it is not possible to establish a correction profile (offsets) to compensate for the weight-induced shifts observed in the data provided by the sensor.

What has been needed, and heretofore unavailable is a system of method of controlling the level of friction present between a fiber and an encapsulation tube so that the elastic strain, including the strain caused by the weight of the fiber, is kept within a pre-determined range for the useful range of strain and temperature loading of the encapsulation tube in which the fiber is contained. The present invention provides these and other benefits.

### SUMMARY OF THE INVENTION

In a general aspect, the invention includes a method of controlling the level of friction present between a fiber and an encapsulation tube so that the elastic strain, including the strain caused by the weight of the fiber, is kept within a pre-determined range for the useful range of strain and temperature loading of the encapsulation tube in which the fiber is contained.

In another aspect of the invention, a friction reducing substance, such as graphite, is included within the lumen of an encapsulation tube such that the graphite controls the frictional interaction between an optical fiber encapsulated within the lumen and the walls of the encapsulation tube. Alternatively, a coating can be applied to the fiber itself or to the inner wall of the tube to achieve the desired friction between the fiber and the inner tube wall.

In still another aspect of the invention, the friction between the optical fiber and the walls of the encapsulation tube is controlled such that the friction between the fiber and tube walls is large enough to counteract the effect of fiber weight in the vertical or inclined sections of the fiber and tube assembly but small enough to avoid large strain-induced errors everywhere along the fiber.

Other features and advantages of the invention will become apparent from the following detailed description, taken in conjunction with the accompanying drawings, which illustrate, by way of example, the features of the invention.

### BRIEF DESCRIPTION OF THE DRAWINGS

FIG. 1 is cut-away view depicting a length of optical fiber within an encapsulation tube and also showing the inclusion of a friction controlling substance within the tube.

FIG. 2 is a graph illustrating the errors caused by large tensile strains on a fiber Bragg grating temperature sensing array having a length of 16.7 meters.

FIG. 3 is a graph illustrating the effect of varying the EFL on the amount of strain transferred to optical fiber sensors operably connected to the length of optical fiber of FIG. 1 when tension is applied on the encapsulation tube and latter released

FIG. 4 is a schematic representation of the forces present on an element of fiber inside a horizontal tube.

FIG. 5 is a schematic representation of the forces present on an element of fiber inside a vertical tube.

FIG. 6 is a representation of the general helical configuration of an optical fiber inside an encapsulation tube showing two locations where the helix reverses direction.

FIG. 7 depicts the results of a sample calculation of the ‘stick’ and ‘slip’ energy differentials (normalized to δε=1).

FIG. 8 illustrates the calculated and measured strain induced errors for different values of the friction coefficient μ with and without a substance used to control the friction coefficient between an optical fiber and the inner wall of an encapsulating tube.

FIG. 9 illustrates the relationship between frictional force and fiber weight for various combinations of fiber diameter and tube diameter, and for varying amounts of EFL.

### DETAILED DESCRIPTION OF THE PREFERRED EMBODIMENTS

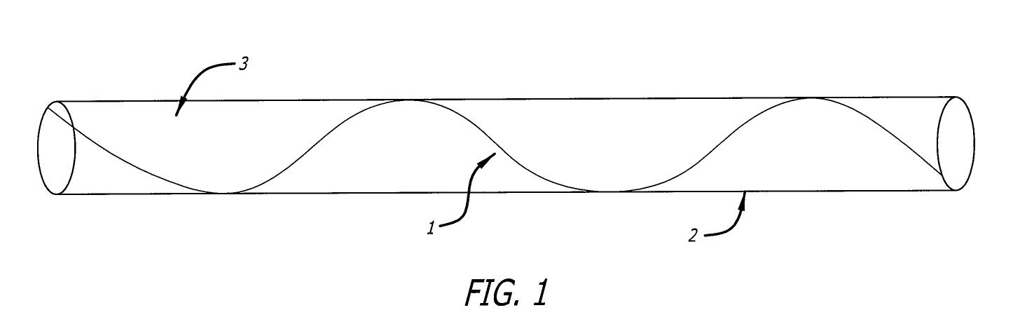

Referring now to the drawings in detail, FIG. 1 shows an optical fiber 1 that may contain one or more fiber Bragg grating sensors or sensor arrays disposed within the tubular cavity (interior lumen) of an encapsulation tube 2. Such a construction may be used to package fiber optic pressure or temperature sensors. Encapsulation of the fiber within an encapsulation tube helps protect the optical fiber such that the optical fiber sensor or sensor array in harsh environments, such as the environment present within an oil or gas well.

It is well known that mechanical and thermal tensile strain within the encapsulation tube can be transferred to the optical fiber via the end boundaries. For example, connectors at the fiber ends may be fixed to both the fiber and the encapsulation tube, thus allowing any strain induced in the encapsulation tube to be transmitted to the optical fiber. Because such tension could result in breakage of the optical fiber, methods have been developed in the art to ensure that the fiber is longer than the encapsulating tube. Such an excess fiber length is commonly referred to as EFL. One exemplary method of providing EFL in an encapsulated tube assembly is disclosed in U.S. Pat. No. 5,318,215 issued to Toya et. al., which is hereby incorporated herein in its entirety.

Even though the presence of EFL reduces the chance of large amounts of tension stress being applied to the fiber, dimensional changes in the tube can still lead to strain in the fiber by the frictional interaction between the fiber and the inner wall of the encapsulation tube. Such friction can give rise to tensile or compressive strain in the fiber, depending on the thermo-mechanical loading of the encapsulation tube. In particular, the inventors have found that when the temperature is decreased, or tension in the tube is released, and depending on the amount of EFL present, large compressional strain can be coupled to the optical fiber. In some cases the magnitude of the transferred strain is equal to the case of the fiber being fully bound to the encapsulation tube.

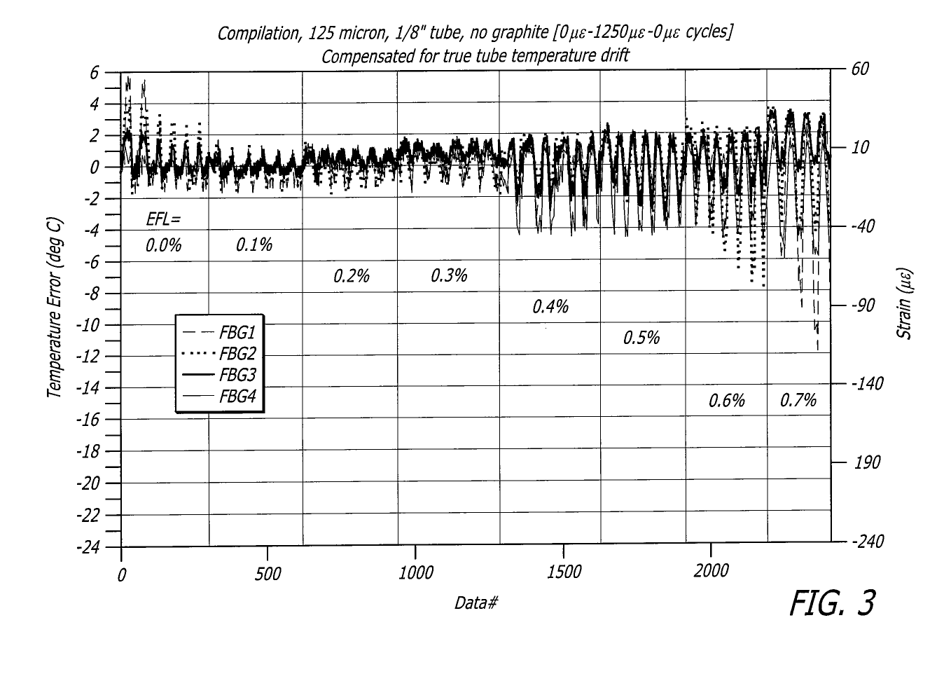

FIG. 3 illustrates this observation for the case of four Fiber Bragg Gratings (FBGs) written in an 8 meter long optical fiber and then encapsulated in an 0.125 inch OD, 0.095 inch ID stainless steel tube. An important observation with regard to the results shown in FIG. 3 is that for the range of EFL between 0.1% and 0.3%, the temperature error is within +/−2 degrees Celsius whereas it is larger for other values of EFL. While this result is particular to the case represented by the graph in FIG. 3, the result illustrates that for a given fiber and encapsulation tube configuration, the strain-induced errors will be a function of the amount of EFL present. Using this observation, including the effect of other key factors, such as tube size, the elastic properties of the fiber and the coating materials, and the coefficient of friction between the materials, the inventors have devised a general methodology to design arrays with errors within a desired range.

One presently preferred embodiment of the invention relies on the fact that frictional strain coupling to the fiber is an energy-based stick-slip phenomenon: When the encapsulation tube changes dimension, that is, when it is strained by thermal strain on the encapsulation tube, the optical fiber will be strained by the same amount for as long as doing so requires less energy than if the fiber slips within the encapsulation tube. In the case where ‘stick’ occurs, the energy expended is elastic strain energy in the fiber and its coating. In the ‘slip’ case, the energy is dissipative and is a function of the frictional force present between the fiber and the wall.

In differential form, considering small increments of strain in the encapsulation tube 6E, the energy required for slippage is:

δUₜₒₜₐₗ^{slip}=δUₜₒₜₐₗ^{slip}(ε,δ_{EFL},δε)

where the arguments indicate that the energy expended during slippage will, among other factors, depend on the current state of strain of the encapsulation tube (ε), the amount of EFL present (δ_{EFL}), and the size of the strain increment itself (δε), to which δUₜₒₜₐₗ^{slip} is proportional.

The elastic energy associated with the same [symbol] [symbol] if the fiber is sticking to the tube is:

δUₜₒₜₐₗ^{stick}=δUₜₒₜₐₗ^{stick}(ε,δ_{EFL},δε)

Slippage will occur when the elastic energy differential is greater than the slippage term. In other words, the path of lowest energy will be followed. Or, viewed from a different perspective, when δUₜₒₜₐₗ^{stick}(ε,δ_{EFL},δε)>δUₜₒₜₐₗ^{slip}(ε,δ_{EFL},δε), the elastic energy stored in the system is able to supply the energy required for slippage and the slippage occurs. The EFL intervenes in these energy terms in two ways: first, the larger the EFL, the larger the normal force f_{N} acting on the fiber, that is, the force between the wall and the fiber, and second, the EFL determines the initial state of strain of the fiber (ε₀^{f}) with the encapsulation tube unloaded (ε=0). This last point is due to the fact that the larger the EFL, the shorter the pitch of the helix described by the fiber, and compression is required in the fiber to hold this configuration. The analysis consists of calculating the largest negative strain εₘᵢₙ and largest positive strain εₘₐₓ where sticking is present. That is, when εₘᵢₙ≦ε≦εₘₐₓ the fiber sticks to the tube wall, and outside of this range, any change of length of the tube does not transfer to the optical fiber because slippage occurs. Thus, εₘᵢₙ and εₘₐₓ set the largest negative and largest positive errors to be observed.

The evaluation of δUₜₒₜₐₗ^{stick} and δUₜₒₜₐₗ^{slip} requires the calculation of elastic energy changes in the fiber and such calculation can be done using a variety of modeling approaches which comprises an analytical linear elastic model of the axial, bending and torsion terms of elastic energy and their associated differential, or a Finite Element Model of the strain energy terms. In addition to strain energy terms, δUₜₒₜₐₗ^{slip} comprises a dissipative term δU_{friction}^{slip}. In general, the energy differentials will have the following contributions:

δUₜₒₜₐₗ^{stick}(ε,ε₀,δ_{EFL},δε)=δUₐₓᵢₐₗ^{stick}(ε,ε₀,δε)+U_{bending}^{stick}(δ_{EFL},δε)+Uₜₒᵣₛᵢₒₙ^{stick}(δ_{EFL},δε)+Uₛₕₑₐᵣ^{stick}(δ_{EFL},δε)

and

δUₜₒₜₐₗ^{slip}(ε,ε₀,δ_{EFL},δε)=δU_{friction}^{slip}(ε,ε₀,δε)+U_{bending}^{slip}(δ_{EFL},δε)+Uₜₒᵣₛᵢₒₙ^{slip}(δ_{EFL},δε)+Uₛₕₑₐᵣ^{slip}(δ_{EFL},δε)

FIG. 5 shows a sample result of an analytical model calculation that shows the resulting positive and negative strain-induced errors on a temperature sensing FBG array encapsulated in a 0.125″ OD, 0.095″ ID stainless steel tube. The fiber is 80 micron in diameter with a 110 micron diameter polyimide coating. In the model used for this example, the slippage term is dominated by the dissipative term which as follows:

$$δ {U}_{friction}^{slip} ( ɛ , {ɛ}_{0} , δɛ ) = \frac{μ \cdot {f}_{N} ( ɛ , {ɛ}_{0} )}{2} ( \frac{{L}_{0}^{2}}{sin ( θ )} ) [ {cos}^{2} ( θ ) - υ \cdot {sin}^{2} ( θ ) ] \cdot \vert δɛ \vert$$

where θ is the angle made between the fiber helix and the axis of the tube and L₀ is the average distance between two helix reversals inside the tube (FIG. 6), μ is the coefficient of friction, ν is the Poisson ratio of the tube material, and f_{N} is the value of the normal force between the fiber and the tube wall.

f_{N} is dependent on the size of the optical fiber, any coatings applied to the fiber, including the thickness of the coating, and the amount of EFL present. The minimum EFL required is determined as a function of the thermal expansion coefficient mismatch between the tube and the fiber, and is thus a function of the temperature range to which the fiber will be exposed to. Control of μ is achieved either by coating the fiber or the inner wall of the tube with a material, such as polytetrafluoroethylene (PTFE), or by using a dry lubricant, such as graphite or other suitable dry lubricant, within the encapsulation tube.

It should be clear from the above discussion that for a given fiber and encapsulation tube configuration, it is possible to calculate and/or determine the strains at which slippage onset between the fiber and tube will occur. These strains are ε^{max} and ε^{min} for the cases of tension and compression, respectively. The inventors have also made the important observation that for certain combinations of fiber and encapsulation tube dimensions and coefficient of friction there exist a critical value of EFL above which, when loading in compression, no slippage occurs and very large negative errors due to compressive strain can be present in the sensor measurements denoted as δ_{EFL}^{max}.

The inventors have determined that it is desirable to select an EFL, and to include a dry lubricant within the tube to minimize friction effects such that:

A·f_{w}<μ·f_{N}(δ_{EFL})<μ·f_{N}(δ_{EFL}^{max(μ))}

where f_{w} is the fiber weight (per unit length), A is a margin factor greater than 1, and δ_{EFL}^{max}(μ) is the threshold value mentioned before, with the argument indicating that its value will also depend on the coefficient of friction, above which no slippage occurs in compression, leading to large errors.

Selection of EFL is also important in controlling tensile strain on the fiber. Having sufficient EFL is important in avoiding tensile strain on a fiber that can lead to breakage of the fiber. However, the EFL selected for use in a sensor array may be too large and may create large frictional tensile strain, and even larger compressive errors. Thus it is important to select an EFL which minimizes tensile strain on the fiber, but is not so large at to result in measurement errors due to increased friction due to the increased amount of fiber or increased compressive stress. A typical value for EFL may be, for example, 0.7%. The temperature of operation affects the effective EFL present in the tube and must be accounted for in selecting sensor parameters.

The margin parameter A is a dimensionless variable. Depending on the level of vibration present, this number needs to be larger to prevent the fiber from slipping. The inventors have determined that this value should be at least greater than 1, and preferably between two and three.

In one embodiment of the present invention, a 125 μm diameter fiber is coated with a polyimide coating resulting in a coated diameter of 155 μm. The coated fiber is encapsulated inside a dual-layer tube (a tube within a tube) having an inner diameter of 0.095 inches and an outer diameter of the 0.125 inches. The dual-layer tube is manufactured from 316 L stainless steel. To provide for thermal expansion of the tube, the EFL of the fiber is chosen to be 0.7%. That is, the length of the fiber within the tube is 0.7% longer than the length of the tube. A powdered graphite, such as grade ASB-Microfyne-P, is blown into the tube after insertion of the fiber to provide lubrication between the fiber and the inner wall of the tube. The amount of graphite, as well as the particle size of the graphite, is selected to provide a desired coefficient of friction between the fiber and inner tube wall. In this embodiment, the tube is not filled solid with graphite so that there is still space between the fiber and the inner wall of the tube so that the fiber may move within the tube as necessary, depending on the forces acting on the fiber. It has been shown that the graphite adheres to both the fiber and the inner walls of the tube, minimizing migration of the graphite even when the tube and fiber combination are installed in a vertical orientation. Alternatively, a coating of a suitable material, such as TEFLON, may be applied either to the exterior of the optical fiber or to the interior wall of the encapsulation tube to control the amount of friction between the optical fiber and the encapsulation tube.

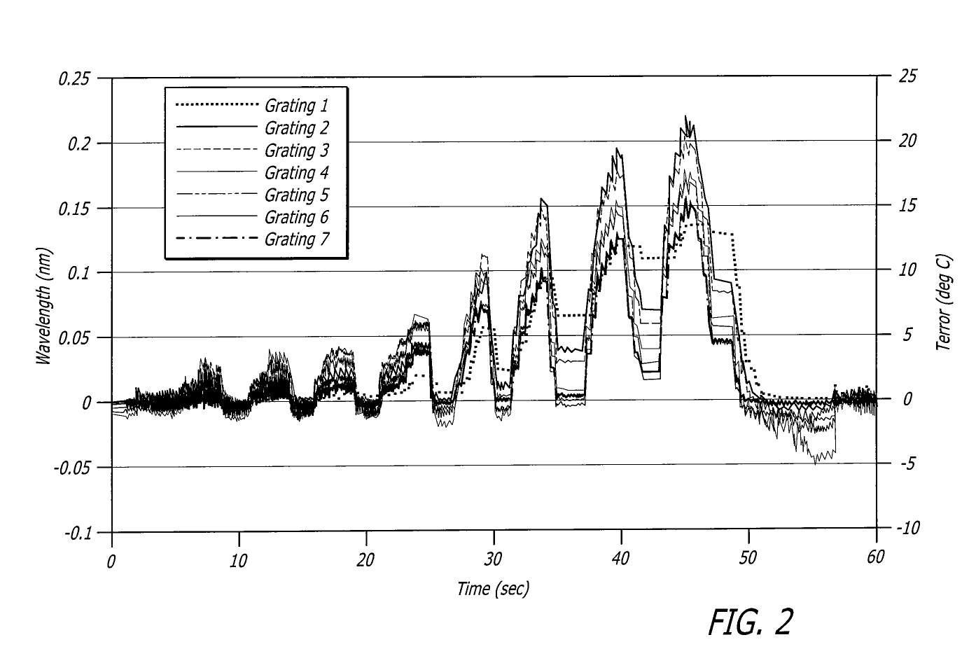

FIG. 2 illustrates the errors caused by large tensile strains on a fiber Bragg grating temperature sensing array having a length of 16.7 meters. The fiber is encapsulated in a 0.52 inch diameter stainless steel tube, and has an EFL of 0.0%. In other words, the fiber is the same length as the tube and one end of the fiber are mounted freely within the tube.

FIG. 3 illustrates the effect of varying the EFL on the amount of strain transferred to optical fiber sensors operably connected to the optical fiber of FIG. 1 when tension is applied on the encapsulation tube and latter released (right scale). The equivalent temperature error is also presented (left scale). The ratio of equivalence is approximately 10με=1° C. of error. In this example, a 125 micron (μm) fiber is mounted in a 0.125 inch outer diameter stainless steel tube. The graphed results are corrected for true tube temperature drift.

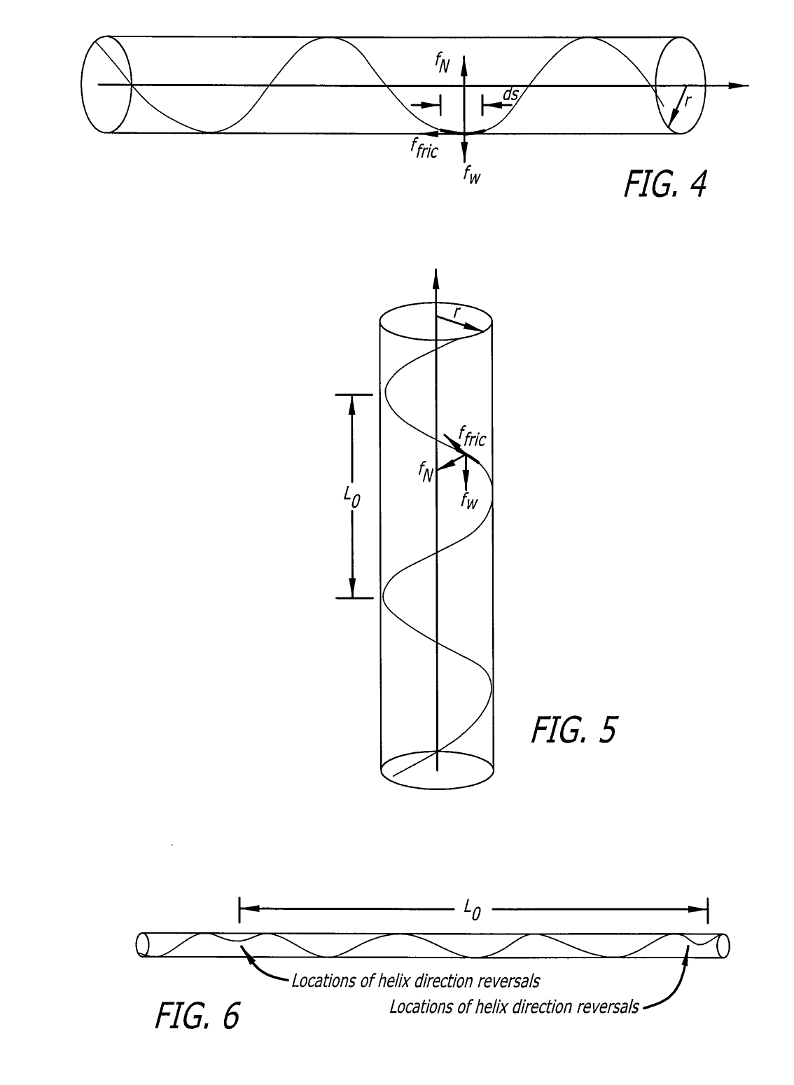

FIG. 4 is a schematic representation of an optical fiber disposed within a horizontal tube illustrating the forces present on an element of the fiber.

FIG. 5 is a schematic representation of an optical fiber disposed within a vertical tube illustrating the forces present on an element of the fiber. A comparison of the forces shown in FIG. 5 to the forces shown in FIG. 4 illustrates the different forces that can be applied to an optical fiber depending on the orientation of the encapsulation tube when the optical fiber and encapsulation tube assembly is installed. Such differences can affect the accuracy of measurements provided by sensors incorporated within the fiber because, as discussed above, the orientation of the assembly results in differing amounts of compressive or tensile strain being imparted to the optical fiber. The method for determining the minimum and maximum amounts of compressive and tensile strain permitted while ensuring that measurements provided by sensors incorporated within the optical fiber fall within acceptable limits thus offers an important tool for providing accurate sensors that may be installed in any orientation. The ability to calculate and apply such limits to the design and manufacture of the optical fiber and encapsulation tube assembly thus provides for improved performance of an optical sensor array and minimizes any costs associated with fine tuning the assembly to control measurement errors.

FIG. 6 is a representation the general helical configuration on an optical fiber inside an encapsulation tube showing two locations where the helix reverses direction. In analytical models, the distance between these reversals is important and is denoted here as L₀.

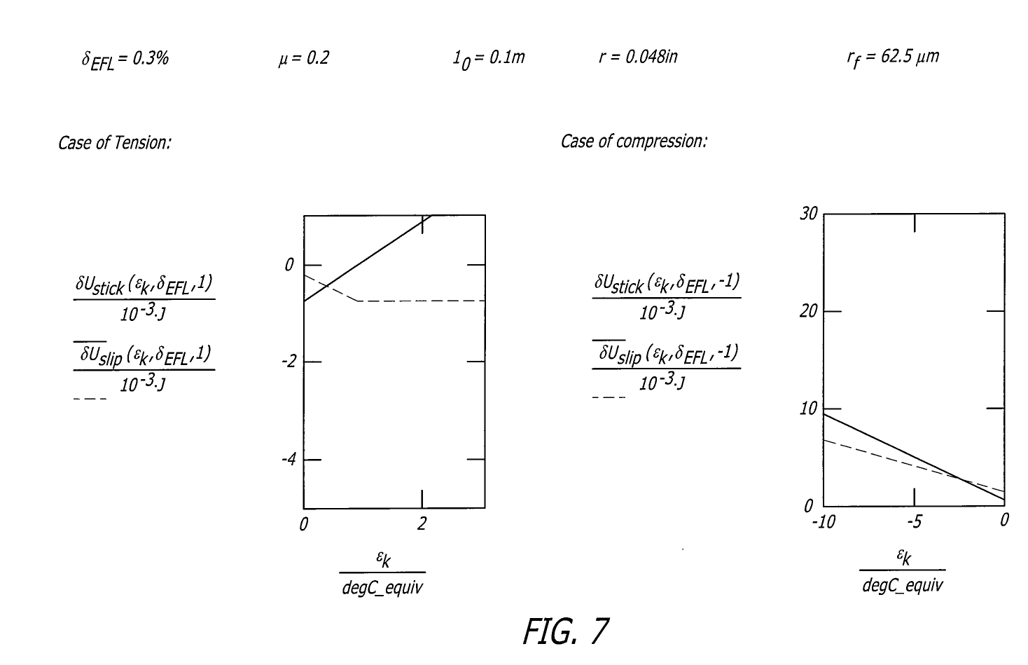

FIG. 7 depicts the results of a sample calculation of the ‘stick’ and ‘slip’ energy differentials (normalized to δε=1). Onset of slippage in both the tensile case or compression case occur at the strain values where the two curves intersect, yielding εₘₐₓ and εₘᵢₙ respectively.

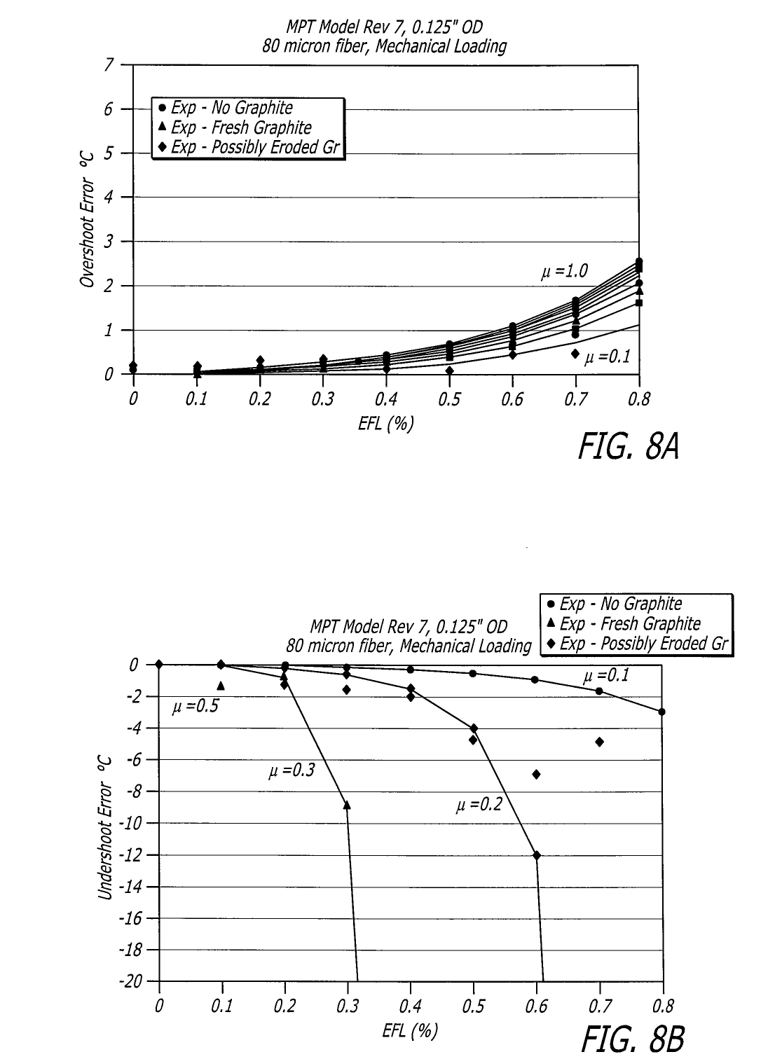

FIG. 8 depicts a pair of graphs showing calculated strain induced errors. The effect of the inclusion of a lubricant, here graphite, is easily discernible and shows how embodiments of the present invention can be used to control the coefficient of friction between an optical fiber and the inner wall of an encapsulating tube.

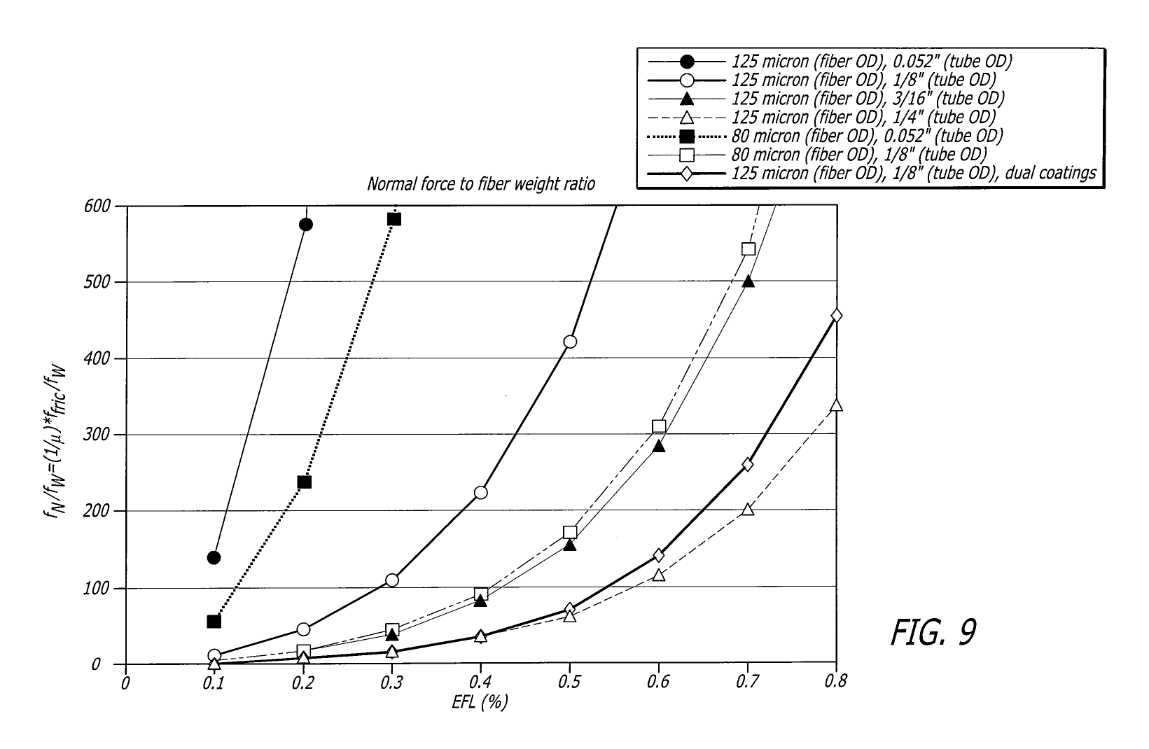

FIG. 9 illustrates the relationship between frictional force and fiber weight for various combinations of fiber diameter and tube diameter, and for varying amounts of EFL.

In one method in accordance with the present invention, an optical fiber in encapsulated within a tube and a lubricant is added to provide a controlled degree of friction between the fiber and tube. In this embodiment, an optical fiber having an outer diameter of about 125 μm is encapsulated in a length of stainless steel tube such that the EFL of the fiber is equal to 0.7%. The sensor is baked for forty-eight hours in an oven to cure the polyimide coating of the fiber. Next, graphite is blown into the tube using nitrogen gas. Typically, the pressure of the nitrogen gas is 600 psi per 1.5 kilometer of tube. The graphite is sucked into the tube using the venturi effect by adding graphite to a manifold connected to one end of the tube. The sensor is then calibrated. After calibration, the ends of the tube are sealed, and connectors are added to the tube and fiber depending the on the intended application of the sensor.

While several particular forms of the invention have been illustrated and described, it will be apparent that various modifications can be made without departing from the spirit and scope of the invention.

We claim:

1. A fiber optic sensor comprising:
a hollow tube;
an optical fiber installed within a lumen of the hollow tube; and
a substance for controlling a coefficient of friction between a wall of the lumen of the hollow tube and the optical fiber is disposed about the optical fiber within the hollow tube;
an array of fiber Bragg gratings formed within a section of the optical fiber.

2. The sensor of claim 1, wherein the hollow tube has a length and the optical fiber has an extra fiber length, and wherein the extra fiber length is selected such that tensile and compressive strain on the optical fiber is limited to a predetermined range.

3. The sensor of claim 1, wherein the optical fiber has an outer diameter and the lumen of the hollow tube has an inner diameter, and wherein the values for the outer diameter of the optical fiber and inner diameter of the lumen are selected to cooperate with the substance for controlling the coefficient of friction such that tensile and compressive strain on the optical fiber is limited to a predetermined range.

4. The sensor of claim 1, wherein the substance for controlling the coefficient of friction is a lubricant.

5. The sensor of claim 4, wherein the substance is graphite.

6. The sensor of claim 1, wherein the substance is a coating disposed around the optical fiber.

7. The sensor of claim 6, wherein the coating is polytetraflouroethylene.

8. The sensor of claim 1, wherein the substance is a coating disposed on the wall of the lumen of the hollow tube.

9. A method of making the sensor of claim 1.

10. A method of manufacturing and encapsulating a fiber optic sensor to provide for a controlled amount of friction between the array and the encapsulating tube, comprising:
disposing a length of optical fiber within a tube, the length of optical fiber including at least one Bragg grating disposed therein;
disposing a substance for controlling a coefficient of friction between the length of the fiber array and an inner wall of the tube;
sealing the ends of the tube.

11. The method of claim 10, further comprising selecting the length of optical fiber such that an EFL of the optical fiber is appropriate to minimize tensile and compressive strains on the optical fiber.

12. The method of claim 10, further comprising determining at least one parameter affecting the accuracy of measurements performed by the fiber sensor using an energy-based elastic model to calculate maximum values for tensile and compressive strain on the fiber such that maintaining the tensile and compressive strains on the fiber below the maximum values for tensile and compressive strain provides a selected degree of measurement accuracy.
